(19) United States
(12) Patent Application Publication
(10) Pub. No.: US 2026/0173398 A1
(43) Pub. Date: Jun. 18, 2026

(54) SEMICONDUCTOR STORAGE DEVICE AND TRANSISTOR DEVICE

(71) Applicant: Sony Semiconductor Solutions Corporation, Kanagawa (JP)

(72) Inventor: Jun Okuno, Kanagawa (JP)

(21) Appl. No.: 19/126,074

(22) PCT Filed: Dec. 1, 2023
(86) PCT No.: PCT/JP2023/043035

§ 371 Date: Apr. 30, 2025

(30) Foreign Application Priority Data
Dec. 19, 2022 (JP) 2022-201800

(51) Int. Cl. H10B 53/30

(52) U.S. Cl. CPC H10B 53/30

(57) ABSTRACT

Provided is a semiconductor storage device that is small in size and excellent in manufacturability. The semiconductor storage device includes: a semiconductor substrate including a thin-film transistor; a first wiring and a second wiring each stacked over the semiconductor substrate; a contact part that includes a first electrically conductive pillar electrically coupling the thin-film transistor and the first wiring to each other; and a capacitor part that includes a second electrically conductive pillar electrically coupling the thin-film transistor and the second wiring to each other. A height position of an upper end, of the first electrically conductive pillar, that is on an opposite side to the semiconductor substrate and a height position of an upper end, of the second electrically conductive pillar, that is on an opposite side to the semiconductor substrate substantially coincide with each other.

### TECHNICAL FIELD

The present disclosure relates to a semiconductor storage device and a transistor device.

### BACKGROUND ART

CMOS (Complementary MOS) circuits each including an n-type field-effect transistor (nMOSFET) and a p-type field-effect transistor (pMOSFET) provided on the same substrate have been known as circuits that consume less power and are operable at high speed. In addition, the miniaturization and high integration of circuits are easy.

Therefore, CMOS circuits are used in a large number of LSI (Large Scale Integration) devices. It is to be noted that such LSI devices have been each commercialized in recent years as SoC (System on a Chip) which consolidates an analog circuit, a memory, a logic circuit, and the like in one chip.

For example, Static RAM (Static Random Access Memory: SRAM) or the like is used for a memory mounted on an LSI device. In recent years, it has been considered to use Dynamic RAM (DRAM), Magnetic RAM (MRAM), Ferroelectric RAM (FeRAM), or the like in place of SRAM to reduce the cost and the power consumption of an LSI device more. Here, the FeRAM is a semiconductor storage device that stores information by using the direction of the remanent polarization of a ferroelectric. A semiconductor storage device functioning as such FeRAM using a ferroelectric capacitor has been proposed (for example, PTL 1).

### CITATION LIST

### Patent Literature

PTL 1: Japanese Unexamined Patent Application Publication No. 2019-160841

### SUMMARY OF THE INVENTION

Incidentally, in the field of electronic devices such as semiconductor storage devices, miniaturization of dimension is desired.

It is therefore desirable to provide a semiconductor storage device that is small in size and excellent in manufacturability.

A semiconductor storage device according to an embodiment of the present disclosure includes: a semiconductor substrate including a thin-film transistor; a first wiring and a second wiring each stacked over the semiconductor substrate; a contact part including a first electrically conductive pillar, the first electrically conductive pillar extending in a stack direction in which the first wiring and the second wiring are each stacked over the semiconductor substrate and electrically coupling the thin-film transistor and the first wiring to each other; and a capacitor part including a second electrically conductive pillar, the second electrically conductive pillar extending in the stack direction and electrically coupling the thin-film transistor and the second wiring to each other. Here, a height position of an upper end, of the first electrically conductive pillar, that is on an opposite side to the semiconductor substrate and a height position of an upper end, of the second electrically conductive pillar, that is on an opposite side to the semiconductor substrate substantially coincide with each other.

The semiconductor storage device according to the embodiment of the present disclosure is suitable for miniaturization and is easily manufacturable.

### BRIEF DESCRIPTION OF DRAWINGS

FIG. 1 is a circuit diagram illustrating an example of an equivalent circuit of a semiconductor storage device according to a first embodiment of the present disclosure.

FIG. 2 is a schematic diagram illustrating an example of a cross-sectional configuration along a stack direction of the semiconductor storage device illustrated in FIG. 1.

FIG. 3 is a schematic diagram illustrating an example of a planar configuration of the semiconductor storage device illustrated in FIG. 1.

FIG. 4 is a schematic diagram illustrating an example of a cross-sectional configuration along an in-plane direction of the semiconductor storage device illustrated in FIG. 1.

FIG. 5A is a schematic diagram describing a step of a method of manufacturing the semiconductor storage device illustrated in FIG. 1.

FIG. 5B is a schematic diagram illustrating one step subsequent to that in FIG. 5A.

FIG. 5C is a schematic diagram illustrating one step subsequent to that in FIG. 5B.

FIG. 5D is a schematic diagram illustrating one step subsequent to that in FIG. 5C.

FIG. 5E is a schematic diagram illustrating one step subsequent to that in FIG. 5D.

FIG. 5F is a schematic diagram illustrating one step subsequent to that in FIG. 5E.

FIG. 5G is a schematic diagram illustrating one step subsequent to that in FIG. 5F.

FIG. 5H is a schematic diagram illustrating one step subsequent to that in FIG. 5G.

FIG. 6 is a schematic diagram illustrating an example of a cross-sectional configuration along a stack direction of a semiconductor storage device according to a first modification example of the first embodiment of the present disclosure.

FIG. 7 is a schematic diagram illustrating an example of a cross-sectional configuration along a stack direction of a semiconductor storage device according to a second modification example of the first embodiment of the present disclosure.

FIG. 8 is a schematic diagram illustrating an example of a cross-sectional configuration along a stack direction of a semiconductor storage device according to a third modification example of the first embodiment of the present disclosure.

FIG. 9 is a schematic diagram illustrating an example of a cross-sectional configuration along a stack direction of a semiconductor storage device according to a fourth modification example of the first embodiment of the present disclosure.

FIG. 10 is a schematic diagram illustrating an example of a cross-sectional configuration along a stack direction of a semiconductor storage device according to a fifth modification example of the first embodiment of the present disclosure.

FIG. 11 is a schematic diagram illustrating an example of a cross-sectional configuration along a stack direction of a semiconductor storage device according to a sixth modification example of the first embodiment of the present disclosure.

FIG. 12A is a schematic diagram illustrating an example of a cross-sectional configuration of a transistor device according to a second embodiment of the present disclosure.

FIG. 12B is another schematic diagram illustrating the example of the cross-sectional configuration of the transistor device according to the second embodiment of the present disclosure.

FIG. 13 is a schematic diagram illustrating an example of a cross-sectional configuration of a transistor device according to a reference example.

FIG. 14 is a schematic diagram illustrating an example of a cross-sectional configuration along a stack direction of a semiconductor storage device according to another first modification example of the present disclosure.

FIG. 15 is a schematic diagram illustrating an example of a cross-sectional configuration along a stack direction of a semiconductor storage device according to another second modification example of the present disclosure.

### MODES FOR CARRYING OUT THE INVENTION

The following describes embodiments of the present disclosure in detail with reference to the drawings. The embodiments described below are specific examples of the present disclosure. The technology according to the present disclosure should not be limited to the following modes. In addition, the disposition, dimensions, dimensional ratios, and the like of the respective components according to the present disclosure are not limited to the modes illustrated in the drawings.

It is to be noted that description is given in the following order.
1. First Embodiment
   1.1. Overview
   1.2. Configuration Example
   1.3. Manufacturing Method
   1.4. Workings and Effects
   1.5. Modification Examples
2. Second Embodiment
   2.1. Configuration Example
   2.2. Workings and Effects
3. Other Modification Examples

### 1. FIRST EMBODIMENT

### 1.1. Overview

First, an overview of a semiconductor storage device 100 according to a first embodiment of the present disclosure is described with reference to FIG. 1. FIG. 1 is a circuit diagram illustrating an example of an equivalent circuit of the semiconductor storage device 100 according to the present embodiment.

As illustrated in FIG. 1, a semiconductor storage device 100 according to the present embodiment includes a capacitor C and a transistor T. The capacitor C stores information. The transistor T controls the selection and non-selection of the capacitor C.

The capacitor C is a ferroelectric capacitor including a first electrode, a second electrode, and a ferroelectric film sandwiched between the first electrode and the second electrode. The capacitor C is able to store 1-bit information by using the direction of the remanent polarization of the ferroelectric film. The capacitor C is electrically coupled to a source line SL at the first electrode and electrically coupled to the source of the transistor T at the second electrode.

The transistor T is a field-effect transistor that controls the application of a voltage to the capacitor C. The transistor T is electrically coupled to the other electrode of the capacitor C at the source and electrically coupled to a bit line BL at the drain. In addition, the transistor 21 is electrically coupled to a word line WL at the gate. The application of a voltage from the word line WL makes it possible to control the state of the channel.

In a case where information is written in the capacitor C, a voltage is first applied to the word line WL in the semiconductor storage device 100. This causes the channel of the transistor T to transition to the on state. After that, the source line SL and the bit line BL each have a potential applied thereto. This applies the electric field corresponding to the information to be written to the ferroelectric film of the capacitor C. This allows the semiconductor storage device 100 to write information in the capacitor C by controlling the direction of the remanent polarization of the ferroelectric film of the capacitor C with an external electric field.

In contrast, in a case where information is read out from the capacitor C, a voltage is first applied to the word line WL in the semiconductor storage device 100. This causes the channel of the transistor T to transition to the on state. After that, the source line SL and the bit line BL each have a predetermined potential applied thereto. This causes the polarization direction of the ferroelectric film of the capacitor C to transition to a predetermined direction. In this case, the magnitude of a current flowing into the capacitor C in a case of transition changes depending on the polarization direction of the ferroelectric film before the transition. The semiconductor storage device 100 is thus able to read out the information stored in the capacitor C by measuring the magnitude of the current flowing into the capacitor C.

This allows the semiconductor storage device 100 to operate as FeRAM (Ferroelectric Random Access Memory) that stores information in the capacitor C including a ferroelectric film.

### 1.2. Configuration Example

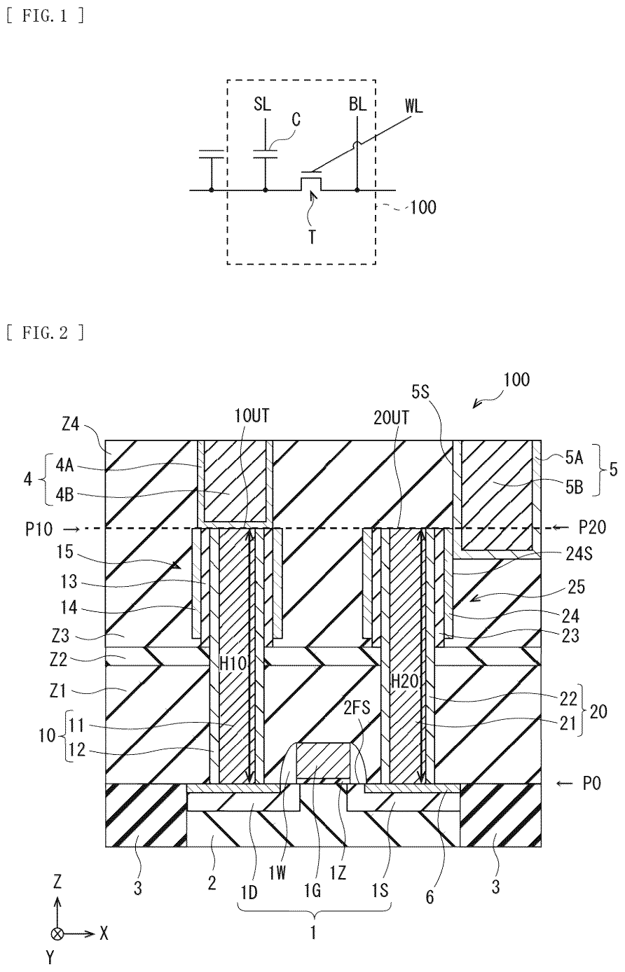

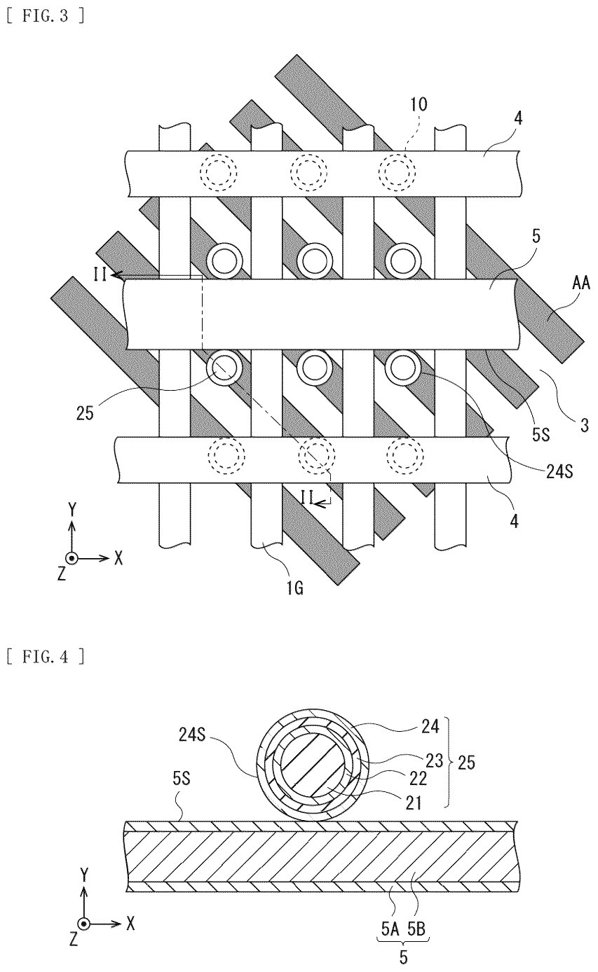

Subsequently, a specific configuration example of the semiconductor storage device 100 according to the present embodiment is described with reference to FIGS. 2 to 4. FIG. 2 illustrates an example of a cross-sectional configuration along a stack direction of the semiconductor storage device 100. FIG. 3 illustrates an example of a planar configuration of the semiconductor storage device 100. FIG. 4 is a cross-sectional diagram illustrating, in an enlarged manner, a portion of the semiconductor storage device 100 in an in-plane direction. It is to be noted that FIG. 3 omits insulating films Z1 to ZA to clarify the disposition of components. The insulating films Z1 to Z4 are formed to extend over the whole surface of a semiconductor substrate 2. Further, the cross-sectional diagram of FIG. 2 illustrates a cross section taken along a line II-II illustrated in FIG. 3. Further, in the present specification, a direction along the plane in which the semiconductor substrate 2 extends is referred to as an in-plane direction, and a direction orthogonal to the in-plane direction is referred to as a height direction or a stack direction. Moreover, FIG. 4 illustrates one capacitor part 25 (to be described later) and a portion of a second wiring 5 (to be described later) included in the semiconductor storage device 100, and omits other components. In FIGS. 2 to 4, the in-plane direction is represented by an XY plane, and the height direction (the stack direction) is represented by a Z-axis direction.

As illustrated in FIG. 2, the semiconductor storage device 100 includes the semiconductor substrate 2, a first wiring 4, the second wiring 5, a contact part 15, and the capacitor part 25 as the capacitor C.

The semiconductor substrate 2 includes a semiconductor material. The semiconductor substrate 2 may be a silicon substrate. Alternatively, the semiconductor substrate 2 may be an SOI (Silicon On Insulator) substrate having an insulating film such as SiO₂ inserted into a silicon substrate. In addition, the semiconductor substrate 2 may be a substrate including another element semiconductor such as germanium. Alternatively, the semiconductor substrate 2 may be a substrate including a compound semiconductor such as GaAs (gallium arsenide), GaN (gallium nitride), or SiC (silicon carbide).

The semiconductor substrate 2 is provided with, for example, a plurality of thin-film transistors 1 and an element isolation layer 3. The element isolation layer 3 includes an insulating material and electrically isolates the plurality of thin-film transistors 1 provided in an active region of the semiconductor substrate 2 from each other. The element isolation layer 3 may include an insulating material such as SiOx (silicon oxide), SiNx (silicon nitride), or SiON (silicon oxynitride).

For example, it is possible to form the element isolation layer 3 by removing a portion of the semiconductor substrate 2 in a predetermined region by etching or the like with an STI (Shallow Trench Isolation) method and then filling an opening formed by etching or the like with SiOx (silicon oxide). Alternatively, the element isolation layer 3 may be formed by thermally oxidizing the semiconductor substrate 2 in a predetermined region with a LOCOS (LOCal Oxidation of Silicon) method.

The region isolated from the periphery by the element isolation layer 3 serves as an active region AA (see FIG. 3) in which the thin-film transistor 1 is provided. For example, an impurity of a first electrical conduction type (e.g., a p-type impurity such as boron (B) or aluminum (Al)) is introduced into the active region AA.

The plurality of thin-film transistors 1 is provided in the vicinity of a surface of the semiconductor substrate 2. As illustrated in FIG. 2, the thin-film transistor 1 is, for example, a MOS (Metal Oxide Semiconductor)-FET (Field-Effect Transistor) including a gate electrode 1G, a side wall insulating film 1W, a gate insulating film 1Z, a drain region 1D, and a source region 1S.

The gate insulating film 1Z includes an insulating material and is provided on the active region AA of the semiconductor substrate 2. The gate insulating film 1Z may include an insulating material known as a gate insulating film of a field-effect transistor. For example, the gate insulating film 1Z may be formed by using an oxide such as silicon oxide (SiOx).

The gate electrode 1G includes an electrically conductive material and is provided on the gate insulating film 1Z. Specifically, the gate electrode 1G extends, for example, in an up-down direction (hereinafter referred to as a first direction) of the paper plane of FIG. 3. Note that the gate electrode 1G is provided to exceed the element isolation layer 3 and extend over a plurality of the active regions AA. This causes the gate electrode 1G to serve as the word line WL that electrically couples the gates of the plurality of thin-film transistors 1.

The gate electrode IG may be formed by using polysilicon or the like. Alternatively, the gate electrode 1G may be formed by using a metal, an alloy, a metal compound, or an alloy of a metal (such as Ni) and polysilicon, i.e., what is called silicide. Specifically, the gate electrode IG may be formed to have a stacked structure of a polysilicon layer and a metal layer including TiN or TaN provided on the gate insulating film 1Z. Such a stacked structure allows the gate electrode 1G to have reduced wiring resistance as compared with a case where the gate electrode 1G is formed by using only a polysilicon layer.

The drain region 1D and the source region 1S are each a region of a second electrical conduction type formed in the semiconductor substrate 2. Specifically, the drain region 1D and the source region 1S are so provided to oppose each other across the gate electrode IG. The drain region 1D and the source region 1S are each a region in which an impurity of the second electrical conduction type (e.g., an n-type impurity such as phosphorus (P) or arsenic (As)) is introduced into the semiconductor substrate 2 in the active region AA. Further, a silicide layer 6 is formed in a portion of a surface 2FS of the semiconductor substrate 2 in each of the drain region 1D and the source region 1S.

The drain region 1D is electrically coupled to, for example, the first wiring 4 as the bit line BL (FIG. 1) via the contact part 15. The source region 1S is electrically coupled to the second wiring 5 as the source line SL (FIG. 1) via the capacitor part 25 as the capacitor C.

The side wall insulating film 132 includes an insulating material and is provided on a side surface of the gate electrode 130 as a side wall. It is possible to form the side wall insulating film 132 by uniformly depositing an insulating film in a region including the gate electrode 130 and then performing vertical anisotropic etching on the insulating film. For example, the side wall insulating film 132 may be formed as a single layer or a plurality of layers by using an insulating oxynitride such as silicon oxide (SiOₓ), silicon nitride (SiNₓ), or silicon oxynitride (SiON).

As illustrated in FIG. 2, the insulating films Z1 to Z4 are sequentially stacked on the thin-film transistor 1. The insulating films Z1, Z3, and Z4 are each, for example, a silicon oxide film, and the insulating film Z2 is, for example, a silicon nitride film.

As illustrated in FIG. 2, the contact part 15 includes a first electrically conductive pillar 10, a ferroelectric layer 13, and an electrode layer 14. The first electrically conductive pillar 10 is a columnar member having a height H10. The first electrically conductive pillar 10 extends in the Z-axis direction through the insulating films Z1 to Z3, for example, from a height position P0 of the surface 2FS of the semiconductor substrate 2 to a height position P10 of an upper surface of the insulating film Z3. The first electrically conductive pillar 10 is positioned between the semiconductor substrate 2 and the first wiring 4 in the Z-axis direction, and electrically couples the thin-film transistor 1 and the first wiring 4 to each other. As illustrated in FIGS. 2 to 4, the first electrically conductive pillar 10 includes, for example, a conductor layer 11 having a substantially circular columnar shape and a barrier metal layer 12 having a substantially cylindrical shape surrounding the periphery of the conductor layer 11. The conductor layer 11 may include, for example, a conductor material such as W (tungsten) or polysilicon. The barrier metal layer 12 may include, for example, a metal material such as Ti (titanium), TiN (titanium nitride), or Ru (ruthenium). The ferroelectric layer 13 and the electrode layer 14 are provided in the same level layer as the insulating film Z3, for example. The ferroelectric layer 13 is so provided as to cover the periphery of the barrier metal layer 12. The electrode layer 14 is so provided as to cover the periphery of the ferroelectric layer 13. A material included in the ferroelectric layer 13 is, for example, the same as a material included in a ferroelectric layer 23 to be described later. A material included in the electrode layer 14 is, for example, the same as a material included in an electrode layer 24 to be described later. It is to be noted that the ferroelectric layer 13 and the electrode layer 14 do not necessarily have to be present.

As illustrated in FIG. 2, a lower end of the first electrically conductive pillar 10 is in contact with the silicide layer 6 provided in the drain region 10D. An upper end 10UT, of the first electrically conductive pillar 10, that is on the opposite side to the semiconductor substrate 2 abuts, for example, a lower surface of the first wiring 4. The first wiring 4 is provided at the same level layer as the insulating film Z4. The first wiring 4 includes, for example, a barrier layer 4A and an embedded layer 4B. The barrier layer 4A may include, for example, a simple substance of each of Co (cobalt), W (tungsten), Mo (molybdenum), Ru (ruthenium), Ta (tantalum), and Cu (copper), or a compound including at least one of these elements. The embedded layer 4B may include an electrically conductive material including Cu (copper) and Ru (ruthenium).

As illustrated in FIGS. 2 and 4, the capacitor part 25 includes a second electrically conductive pillar 20, the ferroelectric layer 23, and the electrode layer 24. The ferroelectric layer 23 is interposed between the second electrically conductive pillar 20 and the electrode layer 24. The second electrically conductive pillar 20 is a columnar member having a height H20. The second electrically conductive pillar 20 extends in the Z-axis direction through the insulating films Z1 to Z3, for example, from the height position PO of the surface 2FS of the semiconductor substrate 2 to a height position P20 of an upper end 20UT. Here, the height position P20 coincides with the height position of the upper surface of the insulating film Z3. In other words, the height position P10 of the upper end 10UT of the first electrically conductive pillar 10 and the height position P20 of the upper end 20UT of the second electrically conductive pillar 20 substantially coincide with each other. The second electrically conductive pillar 20 electrically couples the thin-film transistor 1 and the second wiring 5 to each other. As illustrated in FIGS. 2 to 4, the second electrically conductive pillar 20 includes, for example, a conductor layer 21 having a substantially circular columnar shape and a barrier metal layer 22 having a substantially cylindrical shape surrounding the periphery of the conductor layer 21. The conductor layer 21 may include, for example, a conductor material such as W (tungsten) or polysilicon. The barrier metal layer 22 may include, for example, a metal material such as Ti (titanium), TiN (titanium nitride), or Ru (ruthenium). A material included in the conductor layer 21 is, for example, the same as the material included in the conductor layer 11. A material included in the barrier metal layer 22 is, for example, the same as the material included in the barrier metal layer 12. The ferroelectric layer 23 and the electrode layer 24 are provided in the same level layer as the insulating film Z3, for example. The ferroelectric layer 23 is so provided as to cover the periphery of the barrier metal layer 22. The electrode layer 24 is so provided as to cover the periphery of the ferroelectric layer 23. The ferroelectric layer 23 may include, for example, a ferroelectric material including at least one of HfO₂ (hafnium oxide), Si (silicon), Zr (zirconium), La (lanthanum), Nb (niobium), Y (yttrium), Ge (germanium), or Sc (scandium). The ferroelectric layer 23 may also include PZT (lead zirconate titanate), SBT (bismuth strontium tantalate), or BLT. The electrode layer 24 may include, for example, a metal material such as Ti (titanium), TiN (titanium nitride), or Ru (ruthenium).

A lower end of the second electrically conductive pillar 20 is in contact with the silicide layer 6 provided in the source region 10S. A side surface 24S, of the electrode layer 24 surrounding the second electrically conductive pillar 20, that is on the opposite side to the second electrically conductive pillar 20 abuts, for example, a side surface 5S of the second wiring 5. The second wiring 5 is provided at the same level layer as a portion of the insulating film Z3 and a portion of the insulating film Z4. The second wiring 5 includes, for example, a barrier layer 5A and an embedded layer 5B. The barrier layer 5A may include, for example, a simple substance of each of Co (cobalt), W (tungsten), Mo (molybdenum), Ru (ruthenium), Ta (tantalum), and Cu (copper), or a compound including at least one of these elements. The embedded layer 5B may include an electrically conductive material including Cu (copper) and Ru (ruthenium). A material included in the barrier layer 5A is, for example, the same as the material included in the barrier layer 4A. A material included in the embedded layer 5B is, for example, the same as the material included in the embedded layer 4B.

It is to be noted that, as illustrated in FIG. 3, the second wiring 5 may be shared with an adjacent capacitor part 25.

### 1.3. Manufacturing Method

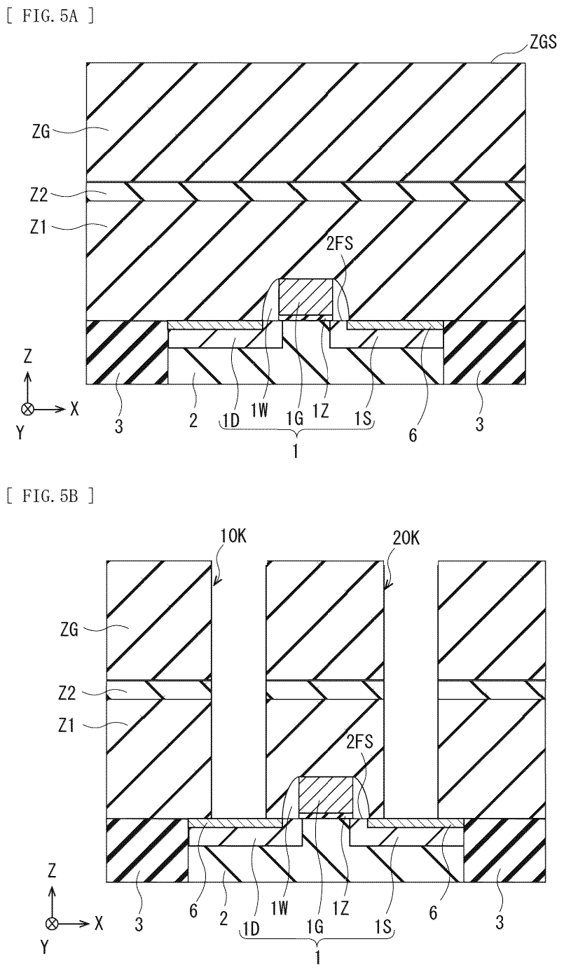

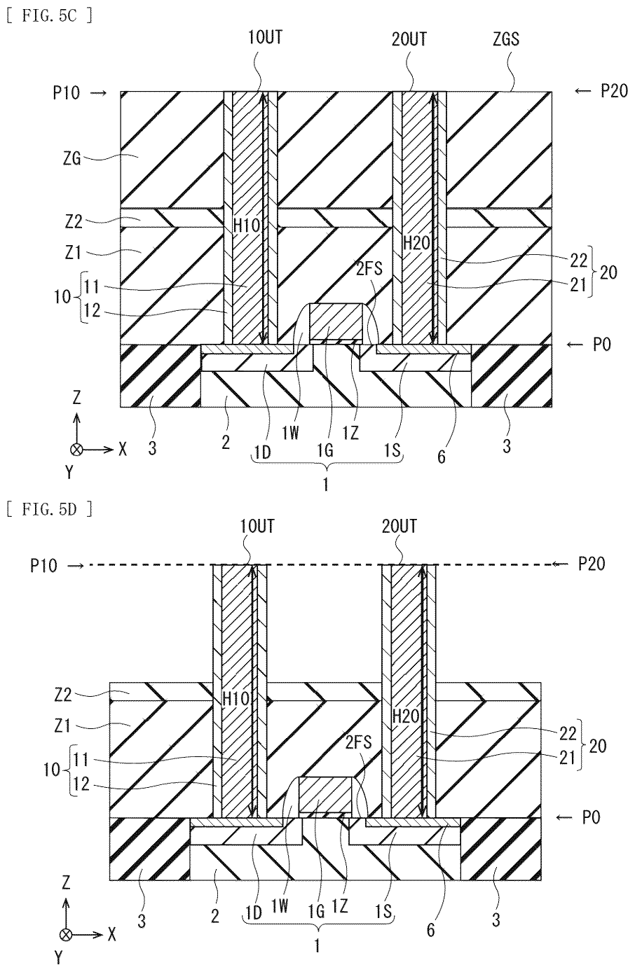

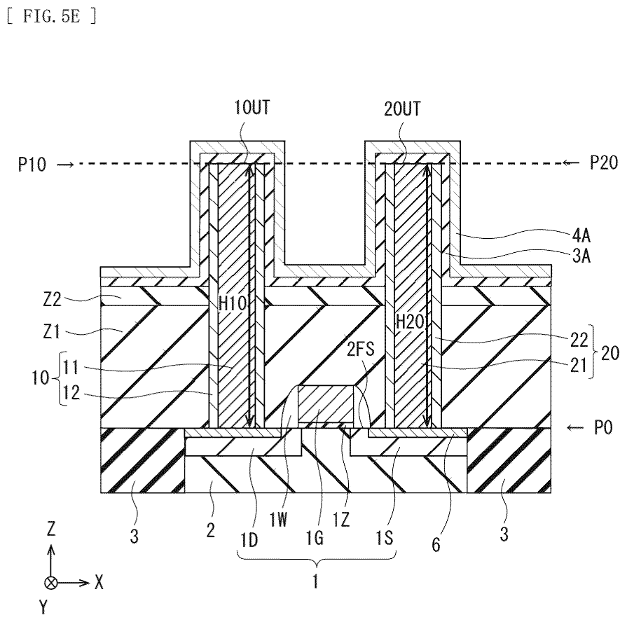

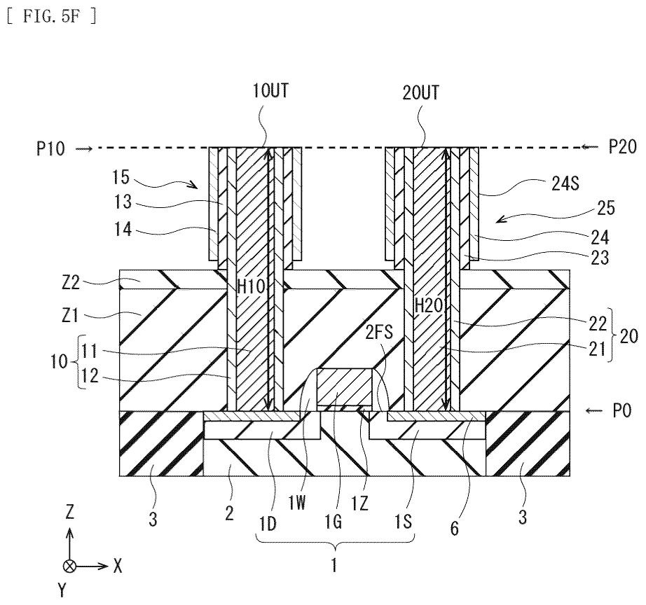

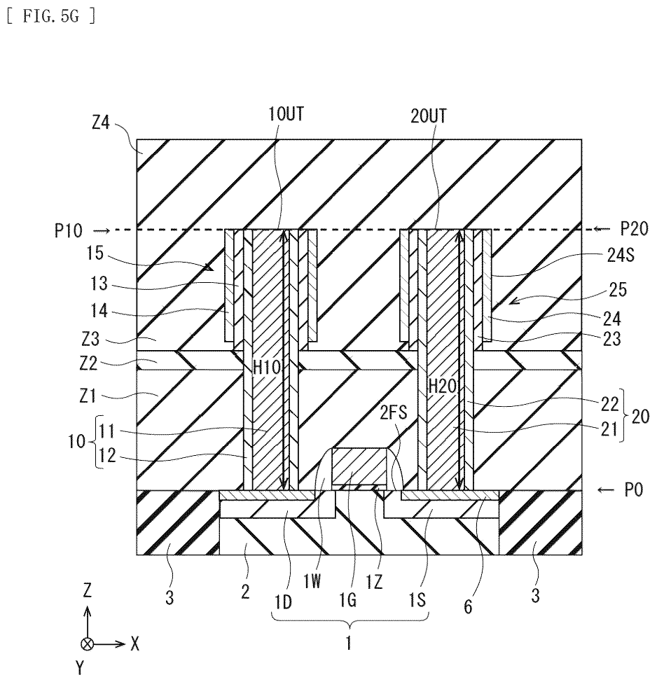

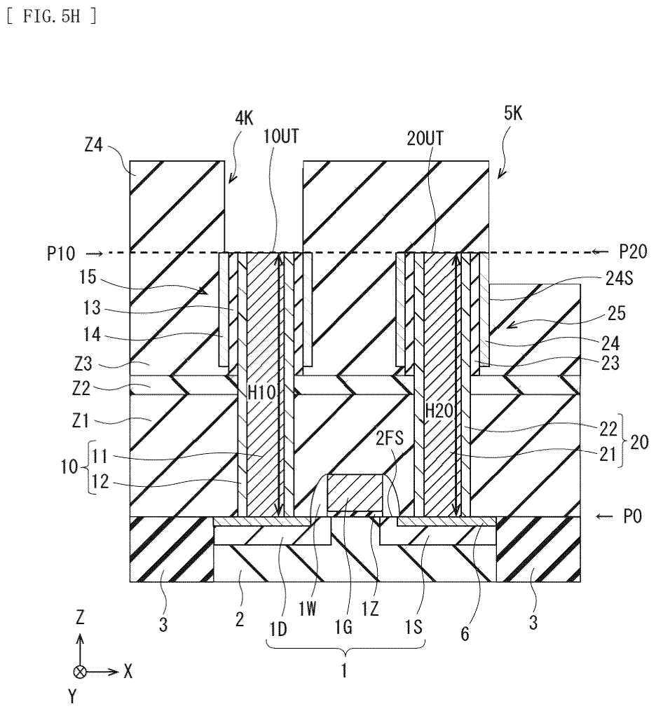

Subsequently, a method of manufacturing the semiconductor storage device 100 according to the present embodiment is described with reference to FIGS. 5A to 5H. FIGS. SA to 5H are schematic diagrams each describing a step of the method of manufacturing the semiconductor storage device 100.

First, as illustrated in FIG. 5A, the element isolation layer 3 is formed in the semiconductor substrate 2.

Specifically, the semiconductor substrate 2 including Si is prepared, following which a SiO₂ film is formed on the semiconductor substrate 2 by dry oxidation or the like. Further, a Si₃N₄ film is formed by low-pressure CVD or the like. Subsequently, a resist layer patterned to protect a region in which the active region AA is to be provided is formed on the Si₃N₄ film. After that, the SiO₂ film, the Si₃N₄ film, and the semiconductor substrate 2 are etched to a depth of 350 nm to 400 nm. Next, SiO₂ is deposited to have a film thickness of 650 nm to 700 nm and fills an opening formed by etching. This makes it possible to form the element isolation layer 3. For example, high-density plasma CVD may be used to deposit SiO₂. The high-density plasma CVD exhibits favorable step difference coverage and allows a dense SiO₂ film to be formed.

Subsequently, the excessively deposited SiO₂ film is removed by using CMP (Chemical Mechanical Polishing) or the like, thereby planarizing the surface of the semiconductor substrate 2. It is sufficient if the SiO₂ film is removed by CMP, for example, until the Si₃N₄ film is exposed.

Further, hot phosphoric acid or the like is used to remove the Si₃N₄ film. Next, the surface of the region of the semiconductor substrate 2 corresponding to the active region AA is oxidized to a thickness of about 10 nm to form an oxide film. After that, the semiconductor substrate 2 of the active region AA is converted into a well of the first electrical conduction type by ion-implanting an impurity of the first electrical conduction type (e.g., boron (B) or the like).

Next, the gate insulating film 1Z is deposited. After that, the gate electrode 1G is formed on the gate insulating film 1Z.

Specifically, the oxide film that covers the surface of the semiconductor substrate 2 is first peeled off by using a hydrofluoric acid solution or the like. After that, the gate insulating film 1Z including SiO₂ is formed on the semiconductor substrate 2 to have a film thickness of 1.5 nm to 10 nm by, for example, dry oxidization that uses O₂ or RTA (Rapid Thermal Anneal) treatment. It is to be noted that a mixed gas of H₂/O₂, N₂O, or NO may be used as a gas used for the dry oxidation in addition to O₂. In addition, the use of plasma nitridation to form the gate insulating film 1Z also makes it possible to dope the SiO₂ film with nitrogen.

Next, polysilicon is deposited to have a film thickness of 50 nm to 150 nm by using low-pressure CVD in which a SiH₄ gas is used as a raw material gas and the deposition temperature is set at 580° C. to 620° C. After that, anisotropic etching is performed on the deposited polysilicon with a patterned resist used as a mask, thereby forming the gate electrode 1G. It is possible to use, for example, a HBr-based gas or a Cl-based gas for the anisotropic etching.

It is to be noted that the gate electrode 11G, 21G may be formed at the same time as, and may be formed to be shared with the gate electrode of another transistor provided in a logic region or the like of a circuit part.

Next, the drain region 1D and the source region 1S are formed in the active region AA of the semiconductor substrate 2. At that time, the side wall insulating film 1W is formed on each of both side surfaces of the gate electrode 1G.

Specifically, SiO₂ is deposited to have a film thickness of 10 nm to 30 nm by plasma CVD. After that, Si₃N₄ is deposited to have a film thickness of 30 nm to 50 nm by plasma CVD to form an insulating film for a side wall. After that, anisotropic etching is performed on the insulating film for a side wall to form the side wall insulating film 1W on each of both side surfaces of the gate electrode 11G, 21G.

After that, arsenic (As), which is an impurity of the second electrical conduction type, is ion-implanted at a concentration of 1×10¹⁵ ions/cm² to 2×10¹⁵ ions/cm² at 20 keV to 50 keV and the impurity of the second electrical conduction type is introduced to both sides of the gate electrode 1G. This forms the drain region 1D and the source region 1S in the active region AA on both sides of the gate electrode 1G. Further, RTA (Rapid Thermal Annealing) is performed at 1000° C. for 5 seconds to activate the ion-implanted impurity. This forms the thin-film transistor 1. It is to be noted that it is also possible to activate the impurity by spike RTA to accelerate the activation of the introduced impurity and suppress the diffusion of the impurity.

Subsequently, to bury the thin-film transistor 1, the insulating film Z1 is formed that extends over the whole surface of the semiconductor substrate 2. Specifically, on the semiconductor substrate 2 on which the thin-film transistor 1 is formed, SiO₂, for example, is deposited by using CVD or the like, following which planarization is performed by, for example, a CMP method. This forms the insulating film Z1. Further, on the insulating film Z1, the insulating film Z2 including, for example, SiN and a sacrifice layer ZG including SiO₂ are sequentially stacked using CVD or the like. At this time, the sacrifice layer ZG may be planarized by, for example, a CMP method so that an upper surface ZGS of the sacrifice layer ZG becomes parallel to the surface 2FS of the semiconductor substrate 2.

Next, as illustrated in FIG. 5B, an opening 10K and an opening 20K are formed, each of which passes through the stacked film including the insulating film Z1, the insulating film Z2, and the sacrifice layer ZG. At this time, the silicide layer 6 provided in the drain region 1D is exposed at the bottom of the opening 10K. Further, the silicide layer 6 provided in the source region 1S is exposed at the bottom of the opening 20K.

Next, as illustrated in FIG. 5C, the first electrically conductive pillar 10 is so formed as to fill the inside of the opening 10K, and the second electrically conductive pillar 20 is so formed as to fill the inside of the opening 20K. At this time, the height position P10 of the upper end 10UT of the first electrically conductive pillar 10 and the height position P20 of the upper end 20UT of the second electrically conductive pillar 20 coincide with a height position of the upper surface ZGS of the sacrifice layer ZG. That is, the height H10 of the first electrically conductive pillar 10 and the height H20 of the second electrically conductive pillar 20 substantially coincide with each other based on the height position PO of the surface 2FS.

Next, as illustrated in FIG. 5D, the sacrifice layer ZG is removed. Here, for example, performing wet treatment with hydrofluoric acid makes it possible to selectively remove the sacrifice layer ZG including the silicon oxide film from the insulating film Z2 including the silicon nitride film, and the first electrically conductive pillar 10 and the second electrically conductive pillar 20 each including the metal material or the like.

Next, as illustrated in FIG. 5E, a ferroelectric material film 3A and an electrode material film 4A are sequentially formed so as to cover the insulating film Z2, the first electrically conductive pillar 10, and the second electrically conductive pillar 20. At this time, for example, it is possible to form the ferroelectric material film 3A and the electrode material film 4A by, for example, an ALD (Atomic Layer Deposition) device, so as to cause the ferroelectric material film 3A and the electrode material film 4A to be sufficiently deposited on a side surface of the second electrically conductive pillar 20.

Next, as illustrated in FIG. 5F, a part of the ferroelectric material film 3A and the electrode material film 4A formed along the XY surface, that is, a part covering the insulating film Z2, a part covering the upper end 10UT of the first electrically conductive pillar 10, and a part covering the upper end 20UT of the second electrically conductive pillar 20 are selectively removed. It is possible to selectively remove the ferroelectric material film 3A and the electrode material film 4A by anisotropic dry etching. Thus, the ferroelectric layer 13 and the electrode layer 14 are stacked and formed on the side surface of the first electrically conductive pillar 10, and the ferroelectric layer 23 and the electrode layer 24 are stacked and formed on the side surface of the second electrically conductive pillar 20. As a result, the contact part 15 and the capacitor part 25 are formed.

Next, as illustrated in FIG. 5G, the insulating film Z3 is formed on the insulating film Z2 so as to fill the periphery of the contact part 15 and the periphery of the capacitor part 25. Further, the insulating film Z4 is formed so as to cover the insulating film Z3, the upper end 10UT, and the upper end 20UT. It is to be noted that the insulating film Z3 and the insulating film Z4 may be collectively formed so that the insulating film Z3 and the insulating film Z4 are integrated with each other. The insulating film Z3 and the insulating film Z4 are formed by forming a silicon oxide film by, for example, a CVD device, following which planarization is performed by a CMP method. Alternatively, the insulating film Z3 and the insulating film Z4 may each be formed with a Spin-on-Dielectric film.

Lastly, the first wiring 4 and the second wiring 5 are formed by, for example, a damascene process. Specifically, as illustrated in FIG. 5H, a portion of the insulating film Z3 and a portion of the insulating film Z4 are selectively removed by a photolithography method to form an opening 4K and an opening 5K, respectively. Next, the barrier layer 4A is formed on the opening 4K and the barrier layer 5A is formed on the opening 5K. After that, the embedded layer 4B is formed so as to fill the opening 4K covered with the barrier layer 4A and the embedded layer 5B is formed so as to fill the opening 5K covered with barrier layer 5A by an electroplating method or the like.

The steps described above make it possible to form the semiconductor storage device 100 illustrated in FIG. 2 and the like.

### 1.4. Workings and Effects

In the capacitor part 25 of such a semiconductor storage device 100, information of “1” or information of “0” is stored according to a polarization state of the ferroelectric layer 23. It is possible to control the polarization state of the ferroelectric layer 23 by applying an electric field to the ferroelectric layer 23. The electric field to be applied to the ferroelectric layer 23 may be controlled by the potential difference between the potential of the gate electrode 1G that is the word line WL (FIG. 1) and the potential of the second wiring 5 as the source line SL (FIG. 1). In the ferroelectric layer 23, the application of the electric field causes polarization, and the polarization state continues even if the electric field is lost. Associating the positive and negative residual polarizations (spontaneous polarizations) caused by the hysteresis of the ferroelectric layer 23 with the logical value “1” or “0” makes it possible to use the capacitor part 25 as a non-volatile memory.

As described above, the semiconductor storage device 100 of the present embodiment includes the semiconductor substrate 2 including the thin-film transistor 1, the first wiring 4 and the second wiring 5, the contact part 15 that includes the first electrically conductive pillar 10 electrically coupling the thin-film transistor 1 to the first wiring 4, and the capacitor part 25 that includes the second electrically conductive pillar 20 electrically coupling the thin-film transistor 1 to the second wiring 5. Here, the height position P10 of the upper end 10UT of the first electrically conductive pillar 10 and the height position P20 of the upper end 20UT of the second electrically conductive pillar 20 are substantially the same as each other. It is therefore possible to collectively form the first electrically conductive pillar 10 and the second electrically conductive pillar 20 in the same step. However, for example, if the first electrically conductive pillar 10 is formed and thereafter the second electrically conductive pillar 20 is to be formed on the same semiconductor substrate 2, it is necessary to form an additional mask for protecting the first electrically conductive pillar 10 that has been formed when the second electrically conductive pillar 20 is formed. In contrast, in the semiconductor storage device 100, the first electrically conductive pillar 10 and the second electrically conductive pillar 20 are collectively formed in the same step. This makes it possible to omit the step of forming such an additional mask. It is therefore possible to easily manufacture the semiconductor storage device 100.

Further, the semiconductor storage device 100 of the present embodiment has a configuration in which the ferroelectric layer 23 and the electrode layer 24 are stacked so as to cover the side surface of the second electrically conductive pillar 20. Thus, the configuration is simpler than that of what is called a cup-shaped capacitor in which a ferroelectric layer and an upper electrode are inserted into a narrow recess of a lower electrode as described in, for example, the above-mentioned PTL 1. That is, the barrier metal layer 22 as a lower electrode, the ferroelectric layer 23, and the electrode layer 24 each have a substantially cylindrical shape and do not have an uneven shape. Accordingly, there are a wide variety of material types that are applicable to materials to be included in the barrier metal layer 22, the ferroelectric layer 23, and the electrode layer 24. Thus, a material type suitable as a capacitor such as W (tungsten) becomes applicable to the lower electrode, and it is possible to achieve the capacitor part 25 having a high capacity. Further, the capacitor part 25 has a simple configuration, which makes it possible to achieve the capacitor part 25 having high dimension accuracy even in a case where the dimension of the capacitor part 25 is reduced. Therefore, the semiconductor storage device 100 is suitable for miniaturization thereof.

Furthermore, in the semiconductor storage device 100 of the present embodiment, the side surface 5S of the second wiring 5 is coupled to the side surface 24S, of the electrode layer 24, that is on the opposite side to the second electrically conductive pillar 20. Therefore, for example, as compared with a case where the ferroelectric layer 23 and the electrode layer 24 are so stacked as to cover the upper end 20UT of the second electrically conductive pillar 20, manufacturing of the semiconductor storage device 100 becomes easier and there is a possibility that a coupling resistance between the electrode layer 24 and the second wiring 5 is reduced.

### 1.5. Modification Examples

### [First Modification Example]

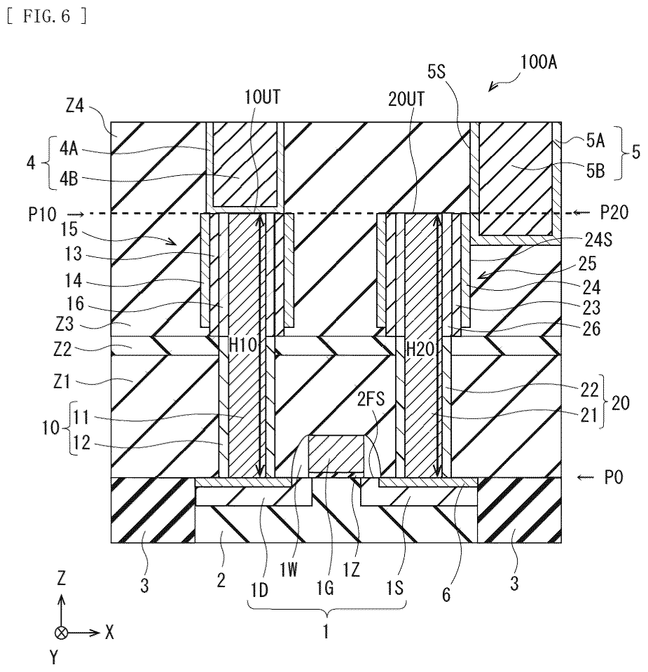

A semiconductor storage device 100A according to a first modification example of the first embodiment of the present disclosure is described with reference to FIG. 6. FIG. 6 is a schematic diagram illustrating a cross-sectional configuration example of the semiconductor storage device 100A. It is to be noted that FIG. 6 corresponds to FIG. 2 illustrating the cross-sectional configuration example of the semiconductor storage device 100 of the first embodiment described above.

In the semiconductor storage device 100A of FIG. 6, a part of the conductor layer 11 of the first electrically conductive pillar 10 above the insulating film Z2 is surrounded by a counter electrode layer 16 instead of the barrier metal layer 12. In the semiconductor storage device 100A, a part of the conductor layer 21 of the second electrically conductive pillar 20 above the insulating film Z2 is surrounded by a counter electrode layer 26 instead of the barrier metal layer 22. That is, a configuration of the semiconductor storage device 100A of FIG. 6 is substantially the same as the configuration of the semiconductor storage device 100 of FIG. 2, except that a portion of the barrier metal layer 12 in the semiconductor storage device 100 of FIG. 2 is replaced with the counter electrode layer 16 and a portion of the barrier metal layer 22 is replaced with the counter electrode layer 26. That is, the counter electrode layer 16 is an upper part surrounded by the ferroelectric layer 13 and the electrode layer 14, and the barrier metal layer 12 is a lower part other than the upper part surrounded by the ferroelectric layer 13 and the electrode layer 14. Similarly, the counter electrode layer 26 is an upper part surrounded by the ferroelectric layer 23 and the electrode layer 24, and the barrier metal layer 22 is a lower part other than the upper part surrounded by the ferroelectric layer 23 and the electrode layer 24. Examples of a material included in each of the counter electrode layer 16 and the counter electrode layer 26 include Al (aluminum), La (lanthanum), TiN (titanium nitride), and TiO (titanium oxide).

The semiconductor storage device 100A of FIG. 6 is manufacturable, for example, as follows. Specifically, after the step of FIG. 5D described in the method of manufacturing the semiconductor storage device 100 of the first embodiment, for example, respective exposed parts of the counter electrode layer 16 and the counter electrode layer 26 (i.e., a part of the counter electrode layer 16 above the insulating film Z2 and a part of the counter electrode layer 26 above the insulating film Z2) are removed by, for example, a wet etching process. Thereafter, the counter electrode layer 16, the ferroelectric layer 13, and the electrode layer 14 are sequentially stacked so as to surround a side surface of the conductor layer 11, and simultaneously, the counter electrode layer 26, the ferroelectric layer 23, and the electrode layer 24 are sequentially stacked so as to surround a side surface of the conductor layer 21. It is possible to perform the subsequent steps in a manner similar to those of the method of manufacturing the semiconductor storage device 100 of the first embodiment to thereby manufacture the semiconductor storage device 100A of FIG. 6.

In the semiconductor storage device 100A of FIG. 6, it is possible to configure the counter electrode layer 26 as the lower electrode using a more preferable material as the capacitor part 25. Therefore, as compared with the semiconductor storage device 100 of FIG. 2, the capacitor part 25 is expected to improve performances thereof including, for example, an increase in the residual polarization in the capacitor part 25, an improvement in rewrite resistance, or an improvement in data-holding property.

### [Second Modification Example]

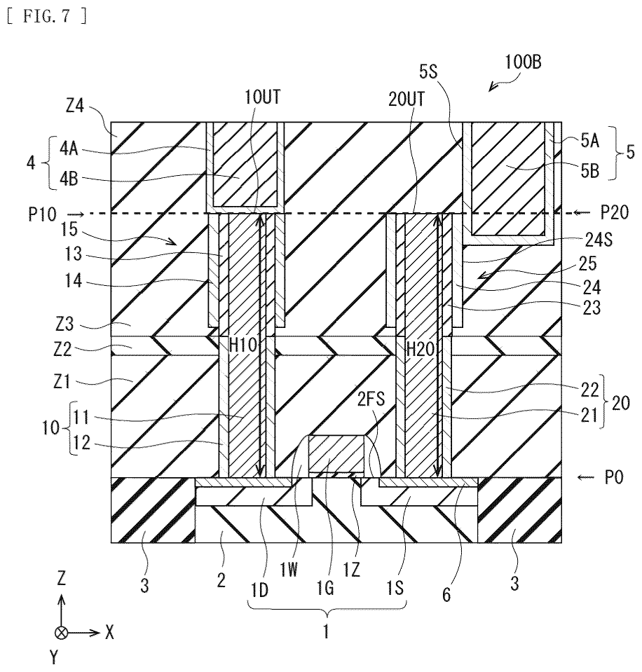

A semiconductor storage device 100B according to a second modification example of the first embodiment of the present disclosure is described with reference to FIG. 7. FIG. 7 is a schematic diagram illustrating a cross-sectional configuration example of the semiconductor storage device 100B. It is to be noted that FIG. 7 corresponds to FIG. 2 illustrating the cross-sectional configuration example of the semiconductor storage device 100 of the first embodiment described above.

In the semiconductor storage device 100B of FIG. 7, a part of the conductor layer 11 of the first electrically conductive pillar 10 above the insulating film Z2 is removed. Further, in the semiconductor storage device 100B, a part of the conductor layer 21 of the second electrically conductive pillar 20 above the insulating film Z2 is removed. Except for those, the configuration of the semiconductor storage device 100B of FIG. 7 is substantially the same as the configuration of the semiconductor storage device 100 of FIG. 2.

The semiconductor storage device 100B of FIG. 7 is manufacturable, for example, as follows. Specifically, after the step of FIG. 5D described in the method of manufacturing the semiconductor storage device 100 of the first embodiment, for example, the respective exposed parts of the counter electrode layer 16 and the counter electrode layer 26 (i.e., a part of the counter electrode layer 16 above the insulating film Z2 and a part of the counter electrode layer 26 above the insulating film Z2) are removed by, for example, a wet etching process. Thereafter, the ferroelectric layer 13 and the electrode layer 14 are sequentially stacked so as to surround the side surface of the conductor layer 11, and simultaneously, the ferroelectric layer 23 and the electrode layer 24 are sequentially stacked so as to surround the side surface of the conductor layer 21. It is possible to perform the subsequent steps in a manner similar to those of the method of manufacturing the semiconductor storage device 100 of the first embodiment to thereby manufacture the semiconductor storage device 100B of FIG. 7.

In the semiconductor storage device 100B of FIG. 7, it is possible to simplify a configuration of each of the contact part 15 and the capacitor part 25, and to reduce a dimension of each of the contact part 15 and the capacitor part 25 in an in-plane direction. In the semiconductor storage device 100B of FIG. 7, it is possible to use the conductor layer 21 instead of the barrier metal layer 22 as the lower electrode of the capacitor part 25. Therefore, it is possible to use tungsten which is unsuitable for film formation by, for example, an ALD method but has a high conductivity as the lower electrode, and the capacitor part 25 is thus expected to improve performances thereof as compared with the semiconductor storage device 100 of FIG. 2.

[third Modification Example]

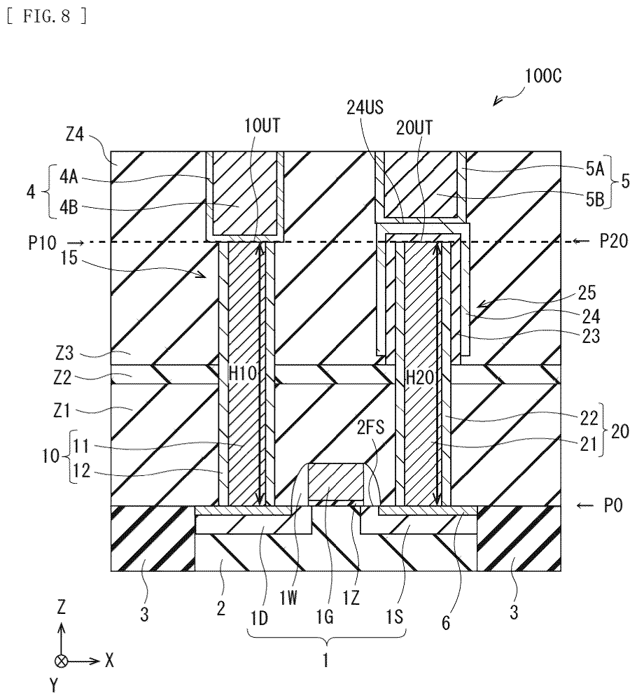

A semiconductor storage device 100C according to a third modification example of the first embodiment of the present disclosure is described with reference to FIG. 8. FIG. 8 is a schematic diagram illustrating a cross-sectional configuration example of the semiconductor storage device 100C. It is to be noted that FIG. 8 corresponds to FIG. 2 illustrating the cross-sectional configuration example of the semiconductor storage device 100 of the first embodiment described above.

In the semiconductor storage device 100C of FIG. 8, the second wiring 5 is provided in a position that overlaps the second electrically conductive pillar 20 in the Z-axis direction. The ferroelectric layer 23 and the electrode layer 24 are provided so as to also cover the upper end 20UT of the second electrically conductive pillar 20. Thus, the capacitor part 25 is coupled to the second wiring 5 not at the side surface 24S of the electrode layer 24, but is coupled to the second wiring 5 at the upper surface 24US of the electrode layer 24. That is, in the semiconductor storage device 100C, the upper surface 24US of the electrode layer 24 is in contact with a lower surface of the barrier layer 5A of the second wiring 5. Further, in the semiconductor storage device 100C of FIG. 8, the contact part 15 has neither the ferroelectric layer 13 nor the electrode layer 14. That is, the contact part 15 only includes the first electrically conductive pillar 10. Except for these points, the configuration of the semiconductor storage device 100C of FIG. 8 is substantially the same as the configuration of the semiconductor storage device 100 of FIG. 2.

The semiconductor storage device 100C of FIG. 8 is manufacturable, for example, as follows. Specifically, after the step of FIG. 5E described in the method of manufacturing the semiconductor storage device 100 of the first embodiment, for example, respective parts, of the ferroelectric material film 3A and the electrode material film 4A, that cover the first electrically conductive pillar 10 and the insulating film Z2 are selectively removed by anisotropic dry etching so as to leave only parts, of the ferroelectric material film 3A and the electrode material film 4A, that cover the second electrically conductive pillar 20. It is possible to perform the subsequent steps in a manner similar to those of the method of manufacturing the semiconductor storage device 100 of the first embodiment. However, the opening 5K is formed immediately above the second electrically conductive pillar 20 so that the upper surface 24US of the electrode layer 24 is exposed at the bottom of the opening 5K. The semiconductor storage device 100C of FIG. 8 is thereby manufacturable.

In the semiconductor storage device 100C of FIG. 8, the second electrically conductive pillar 20 and the second wiring 5 are positioned to overlap each other in the Z-axis direction so that the upper surface 24US of the electrode layer 24 of the capacitor part 25 is coupled to the second wiring 5. It is thus possible to reduce an area of the semiconductor storage device 100C in the in-plane direction as compared with the semiconductor storage device 100 of FIG. 2. Furthermore, in the semiconductor storage device 100C of FIG. 8, the contact part 15 includes neither the ferroelectric layer 13 nor the electrode layer 14, which makes it possible to reduce a parasitic capacity of the contact part 15 as compared with the semiconductor storage device 100 of FIG. 2. It is therefore possible to apply a stable voltage to the thin-film transistor 1.

[fourth Modification Example]

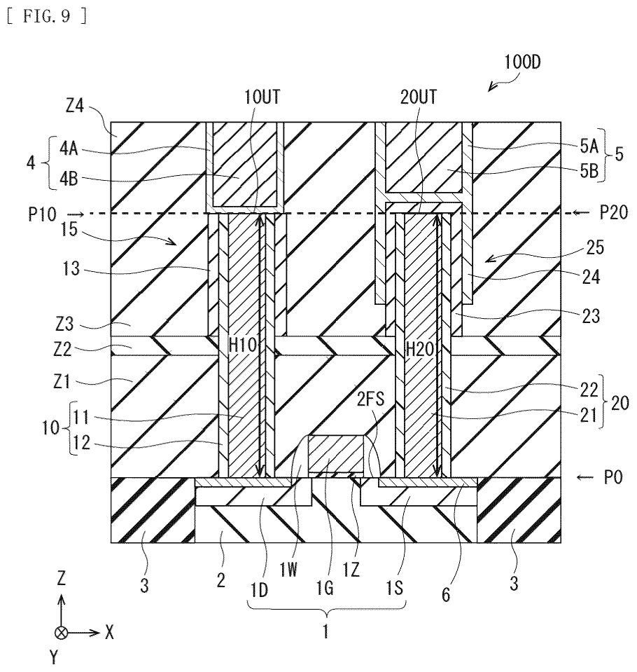

A semiconductor storage device 100D according to a fourth modification example of the first embodiment of the present disclosure is described with reference to FIG. 9. FIG. 9 is a schematic diagram illustrating a cross-sectional configuration example of the semiconductor storage device 100D. It is to be noted that FIG. 9 corresponds to FIG. 2 illustrating the cross-sectional configuration example of the semiconductor storage device 100 of the first embodiment described above.

In the semiconductor storage device 100D of FIG. 9, the second wiring 5 is provided in a position that overlaps the second electrically conductive pillar 20 in the Z-axis direction. The ferroelectric layer 23 is provided so as to also cover the upper end 20UT of the second electrically conductive pillar 20. Further, the electrode layer 24 is integrated with the barrier layer 5A of the second wiring 5. That is, the material included in the electrode layer 24 and the material included in the barrier layer 5A are the same as each other, and the electrode layer 24 also serves as the barrier layer 5A. It is to be noted that the contact part 15 includes no electrode layer 14. That is, the contact part 15 includes the first electrically conductive pillar 10 and the ferroelectric layer 13 surrounding a portion of the first electrically conductive pillar 10. Except for these points, the configuration of the semiconductor storage device 100D of FIG. 9 is substantially the same as the configuration of the semiconductor storage device 100C of FIG. 2.

In the semiconductor storage device 100D of FIG. 9, the second electrically conductive pillar 20 and the second wiring 5 are positioned to overlap each other in the Z-axis direction so that the upper surface 24US of the electrode layer 24 of the capacitor part 25 is coupled to the second wiring 5. It is thus possible to reduce an area of the semiconductor storage device 100D in the in-plane direction as compared with the semiconductor storage device 100 of FIG. 2. Further, in the semiconductor storage device 100D of FIG. 9, the electrode layer 14 of the contact part 15 is absent, and the electrode layer 24 of the capacitor part 25 and the barrier layer 5A of the second wiring 5 are integrated with each other. This makes it possible to omit the step of forming the electrode layer 14 and the electrode layer 24 in a process of manufacturing the semiconductor storage device 100D. It is therefore possible to simplify the process of manufacturing the semiconductor storage device 100D.

[fifth Modification Example]

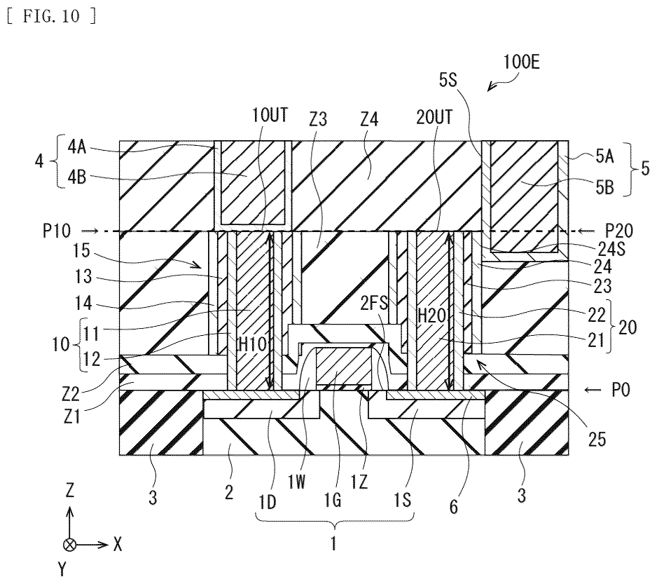

A semiconductor storage device 100E according to a fifth modification example of the first embodiment of the present disclosure is described with reference to FIG. 10. FIG. 10 is a schematic diagram illustrating a cross-sectional configuration example of the semiconductor storage device 100E. It is to be noted that FIG. 10 corresponds to FIG. 2 illustrating the cross-sectional configuration example of the semiconductor storage device 100 of the first embodiment described above.

In the semiconductor storage device 100 illustrated in FIG. 2, the ferroelectric layers 13 and 23 are each provided on the planarized insulating films Z1 and Z2. In contrast, in the semiconductor storage device 100E of FIG. 10, the insulating films Z1 and Z2 are not planarized, and the insulating films Z1 and Z2 each have a conformal shape along a shape of an upper surface of the thin-film transistor 1. Thus, in the semiconductor storage device 100E of FIG. 10, it is possible to decrease the height H10 of the first electrically conductive pillar 10 and the height H20 of the second electrically conductive pillar 20 as compared with the semiconductor storage device 100 of FIG. 2. It is therefore possible for the semiconductor storage device 100E to reduce electric resistance between the thin-film transistor 1 and the first wiring 4 and electric resistance between the thin-film transistor 1 and the second wiring 5, which makes it possible to operate stably as a memory device.

### [Sixth Modification Example]

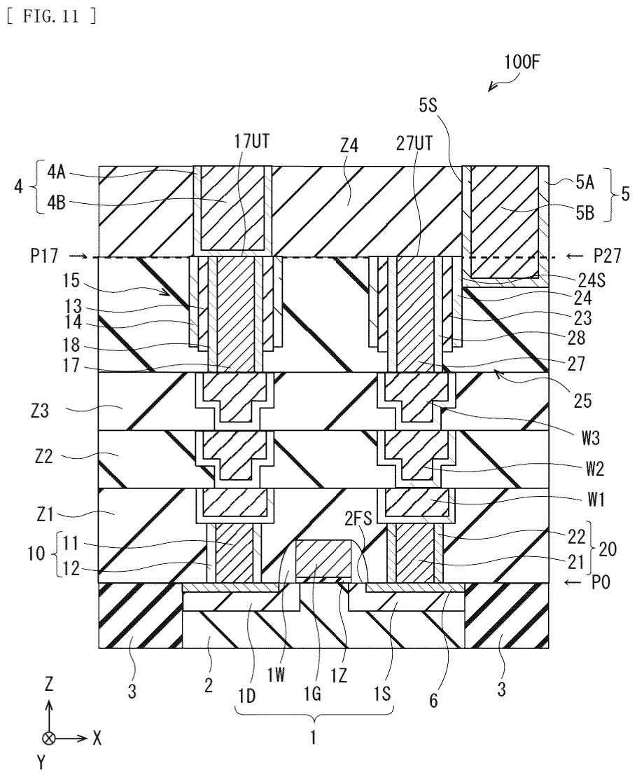

A semiconductor storage device 100F according to a sixth modification example of the first embodiment of the present disclosure is described with reference to FIG. 11. FIG. 11 is a schematic diagram illustrating a cross-sectional configuration example of the semiconductor storage device 100F. It is to be noted that FIG. 11 corresponds to FIG. 2 illustrating the cross-sectional configuration example of the semiconductor storage device 100 of the first embodiment described above.

In the semiconductor storage device 100F of FIG. 11, a plurality of wiring layers W1 to W3 stacked in the Z-axis direction is interposed between the first electrically conductive pillar 10 and the contact part 15, and a plurality of wiring layers W1 to W3 stacked in the Z-axis direction is interposed between the second electrically conductive pillar 20 and the capacitor part 25. The periphery of the wiring layer W1 is filled with the insulating film Z1, the periphery of the wiring layer W2 is filled with the insulating film Z2, and the periphery of the wiring layer W3 is filled with the insulating film Z3. Further, the contact part 15 includes, instead of the first electrically conductive pillar 10, a conductor layer 17 having a substantially circular columnar shape and a barrier metal layer 18 surrounding the periphery of the conductor layer 17. The ferroelectric layer 13 and the electrode layer 14 are provided in the periphery of the barrier metal layer 18. A lower end of the conductor layer 17 is coupled to the wiring layer W3 and an upper end 17UT of the conductor layer 17 is coupled to the first wiring 4. Moreover, the capacitor part 25 includes, instead of the second electrically conductive pillar 210, a conductor layer 27 having a substantially circular columnar shape and a barrier metal layer 28 surrounding the periphery of the conductor layer 27. The ferroelectric layer 23 and the electrode layer 24 are provided in the periphery of the barrier metal layer 28. A lower end of the conductor layer 27 is coupled to the wiring layer W3 and a side surface 24S of the electrode layer 24 is coupled to the side surface 5S of the second wiring 5. In the semiconductor storage device 100F having such a configuration also, a height position P17 of the upper end 17UT of the conductor layer 17 and a height position P27 of an upper end 27UT of the conductor layer 27 may substantially coincide with each other. According to the semiconductor storage device 100F of FIG. 11, flexibility of setting of the heights of the conductor layer 27 and the barrier metal layer 28 is increased, which makes it possible for the capacitor part 25 to acquire, for example, a larger capacity.

### 2. SECOND EMBODIMENT

### 2.1. Configuration Example

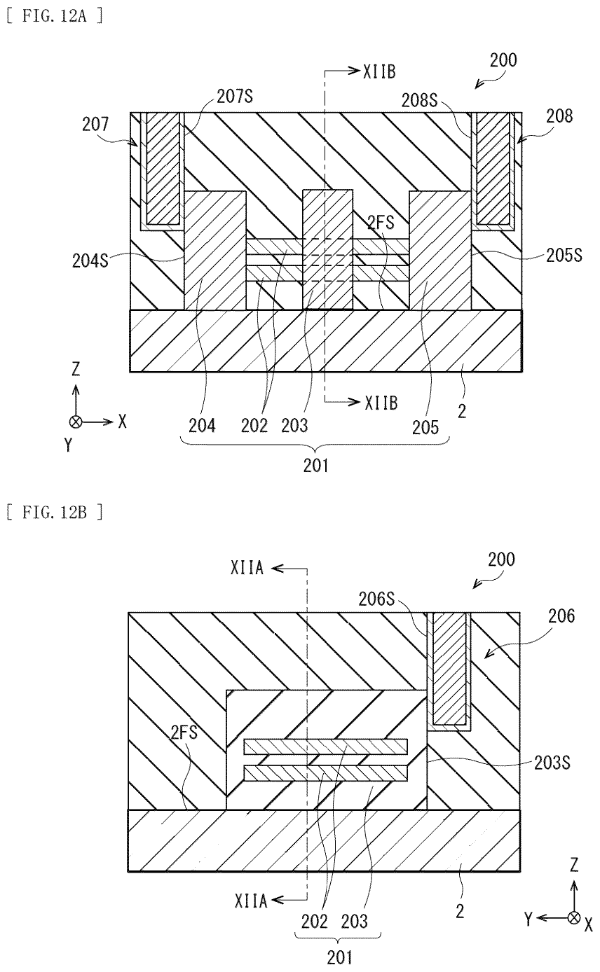

Next, a transistor device 200 according to a second embodiment of the present disclosure is described with reference to FIGS. 12A and 12B. FIGS. 12A and 12B are each a schematic diagram illustrating a cross-sectional configuration example of the transistor device 200. It is to be noted that FIG. 12A illustrates a cross section taken along a XILA-XIIA line direction in FIG. 12B. FIG. 12B illustrates a cross section taken along a XIIB-XIIB line direction in FIG. 12A. That is, the cross section of the transistor device 200 illustrated in FIG. 12A and the cross section of the transistor device 200 illustrated in FIG. 12B are orthogonal to each other.

The transistor device 200 illustrated in FIG. 12 includes a transistor 201 of an advanced technology node. The transistor 201 provided in the semiconductor substrate 2 has a structure that is called what is called a gate-all-around structure. Specifically, the transistor 201 includes a plurality of channel layers 202 each having a sheet shape, a gate electrode 203, a source region 204, and a drain region 205. The gate electrode 203 is formed to cover each of the plurality of channel layers 202. Each of the plurality of channel layers 202 extends along the surface 2FS of the semiconductor substrate 2 and passes through the gate electrode 203 along the surface 2FS. The source region 204 and the drain region 205 are opposed to each other with the gate electrode 203 and the channel layers 202 interposed therebetween, and are each provided upright on the semiconductor substrate 2. The source region 204 and the drain region 205 are, for example, each a region including Si (silicon) formed by epitaxial growth. A side surface 203S of the gate electrode 203, a side surface 204S of the source region 204, a side surface 205S of the drain region 205 are respectively coupled to respective side surfaces of contact plugs 206 to 208.

### 2.2. Workings and Effects

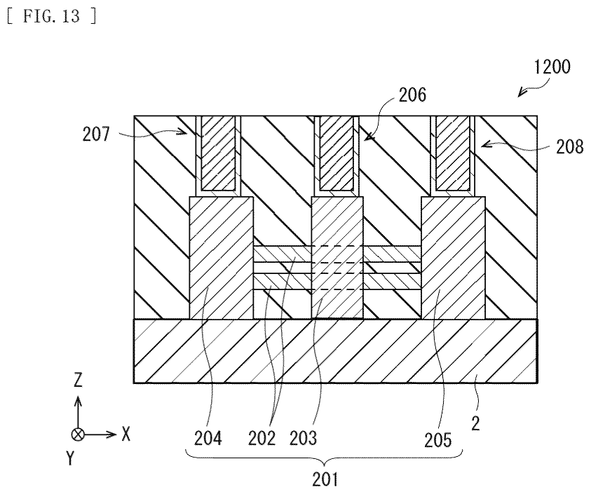

In the transistor device 200 of the present embodiment, as illustrated in FIG. 12A, the side surface 204S of the source region 204 and the side surface 207S of the contact plug 207 are in contact with each other, and the side surface 205S of the drain region 205 and the side surface 208S of the contact plug 208 are in contact with each other. Further, in the transistor device 200, the side surface 203S of the gate electrode 203 and the side surface 206S of the contact plug 206 are in contact with each other as illustrated in FIG. 12B. Accordingly, it is possible to increase a contact area between the gate electrode 203 and the contact plug 206, a contact area between the source region 204 and the contact plug 207, and a contact area between the drain region 205 and the contact plug 208 as compared with, for example, a transistor device 1200 as a reference example illustrated in FIG. 13. The transistor device 1200 is configured such that au upper surface of the gate electrode 203 is in contact with a lower surface of the contact plug 1206, an upper surface of the source region 204 is in contact with a lower surface of the contact plug 207, and an upper surface of the drain region 205 is in contact with a lower surface of the contact plug 208. A transistor of an advanced technology node occupies an extremely small area in the in-plane direction. Thus, an ohmic contact characteristic tends to be deteriorated in such a transistor device 1200 as the reference example. In contrast, in the transistor device 200 of the present embodiment, as described above, the respective side surfaces of the gate electrode 203, the source region 204, and the drain region 205 are each brought into contact with corresponding one of the respective side surfaces of the contact plugs 206 to 208 to ensure sufficient contact areas. Therefore, according to the transistor device 200 of the present embodiment, it is possible to obtain a more favorable ohmic characteristic even in a case where the transistor device 200 is miniaturized.

### 3. OTHER MODIFICATION EXAMPLES

The technology according to the present disclosure has been described above with reference to the embodiments and the modification examples. The technology according to the present disclosure is not, however, limited to the embodiments or the like described above, but a variety of modifications are possible.

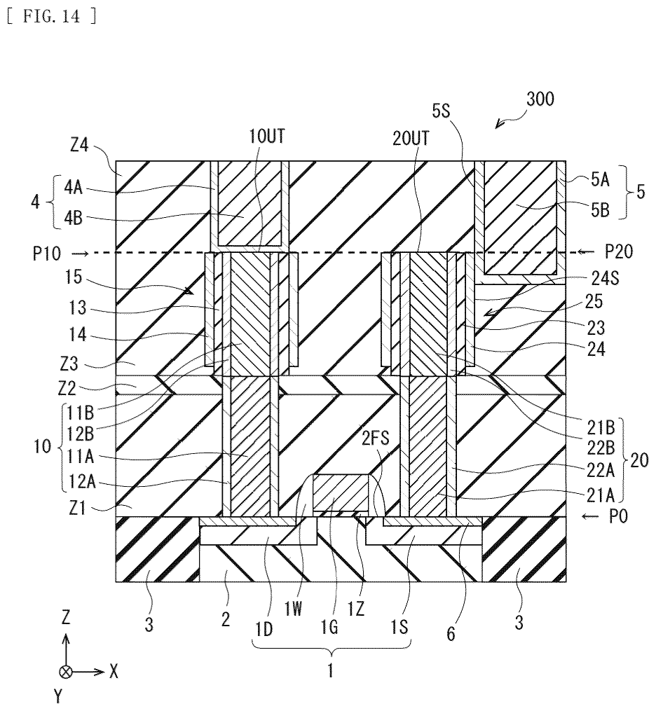

For example, in the semiconductor storage device 100 of the first embodiment described above (see FIG. 2 and the like), the conductor layers 11 and 21 and the barrier metal layers 12 and 22 are each configured as one piece. However, in the present disclosure, the conductor layers 11 and 21 and the barrier metal layers 12 and 22 may each be configured by two or more parts that are divided in the Z-axis direction, for example, as in a semiconductor storage device 300 illustrated in FIG. 14. That is, in the semiconductor storage device 300, the conductor layer 11 has a two-layer structure including a first level layer part 11A and a second level layer part IIB, and the conductor layer 21 has a two-layer structure including a first level layer part 21A and a second level layer part 21B. Similarly, the barrier metal layer 12 has a two-layer structure including a first level layer part 12A and a second level layer part 12B, and the barrier metal layer 22 has a two-layer structure including a first level layer part 22A and a second level layer part 22B. In the semiconductor storage device 300 also, the height position P10 of the upper end 10UT of the first electrically conductive pillar 10 and the height position P20 of the upper end 20UT of the second electrically conductive pillar 20 are substantially the same as each other. It is therefore possible to collectively form the second level layer part 11B of the first electrically conductive pillar 10 and the second level layer part 21B of the second electrically conductive pillar 20 in the same step, and to collectively form the second level layer part 12B of the first electrically conductive pillar 10 and the second level layer part 22B of the second electrically conductive pillar 20 in the same step. However, for example, if the first electrically conductive pillar 10 is formed and thereafter the second electrically conductive pillar 20 is to be formed on the same semiconductor substrate 2, it is necessary to form an additional mask for protecting the first electrically conductive pillar 10 that has been formed when the second electrically conductive pillar 20 is formed. In contrast, in the semiconductor storage device 300, it is possible to collectively form the second level layer part 11B of the first electrically conductive pillar 10 and the second level layer part 21B of the second electrically conductive pillar 20 in the same step, and to collectively form the second level layer part 12B of the first electrically conductive pillar 10 and the second level layer part 22B of the second electrically conductive pillar 20 in the same step. This makes it possible to omit the step of forming such an additional mask. It is therefore possible to easily manufacture the semiconductor storage device 300.

Further, in the semiconductor storage device 300, it is possible to make a material included in each of the first level layer parts 11A and 21A and a material included in each of the second level layer parts 11B and 21B different from each other. Similarly, it is possible to make a material included in each of the first level layer parts 12A and 22A and a material included in each of the second level layer parts 12B and 22B different from each other.

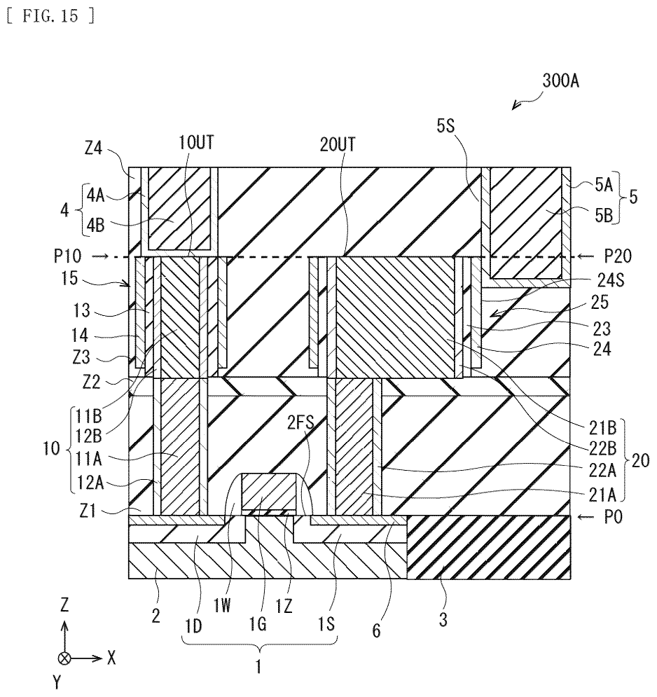

In addition, it is possible to make a cross-sectional area of the first level layer part 21A and a cross-sectional area of the second level layer part 21B different from each other, for example, as in a semiconductor storage device 300A illustrated in FIG. 15. In the semiconductor storage device 300A, as compared with the semiconductor storage device 300, it is possible to increase an area of an opposing part in which the second level layer part 22B and the electrode layer 24 as a pair of electrodes are opposed to each other with the ferroelectric layer 23 interposed therebetween. It is therefore possible to increase capacity of the capacitor part 25.

Further, not all of the components and operations described in the respective embodiments are necessary as the components and operations according to the present disclosure. For example, among components according to the respective embodiments, a component that is not described in an independent claim reciting the most generic concept of the present disclosure should be understood as an optional component.

Terms used throughout this specification and the appended claims should be construed as “non-limiting” terms. For example, the term “including” or “included” should be construed as “not limited to what is described as being included”. The term “having” should be construed as “not limited to what is described as being had”.

The terms used in this specification are used merely for the convenience of description and include terms that are not used to limit the configuration and the operation. For example, the terms such as “right”, “left”, “up”, and “down” only indicate directions in the drawings being referred to. In addition, the terms “inside” and “outside” only indicate a direction toward the center of a component of interest and a direction away from the center of a component of interest, respectively. The same applies to terms similar to these and to terms with the similar purpose.

It is to be noted that the technology according to the present disclosure may have the following configurations. The semiconductor storage device of the present disclosure having the following configurations is small in size and excellent in manufacturability.

It is to be noted that effects attained by the technology according to the present disclosure are not necessarily limited to the effects described herein, but may include any of the effects described in the present disclosure.

### (1)

A semiconductor storage device including:
a semiconductor substrate including a thin-film transistor;
a first wiring and a second wiring each stacked over the semiconductor substrate;
a contact part including a first electrically conductive pillar, the first electrically conductive pillar extending in a stack direction in which the first wiring and the second wiring are each stacked over the semiconductor substrate and electrically coupling the thin-film transistor and the first wiring to each other; and
a capacitor part including a second electrically conductive pillar, the second electrically conductive pillar extending in the stack direction and electrically coupling the thin-film transistor and the second wiring to each other, in which
a height position of an upper end, of the first electrically conductive pillar, that is on an opposite side to the semiconductor substrate and a height position of an upper end, of the second electrically conductive pillar, that is on an opposite side to the semiconductor substrate substantially coincide with each other.

### (2)

The semiconductor storage device according to (1), in which the capacitor part includes
the second electrically conductive pillar,
an electrode layer surrounding a portion of a side surface of the second electrically conductive pillar, and
a ferroelectric layer interposed between the second electrically conductive pillar and the electrode layer.

### (3)

The semiconductor storage device according to (2), in which the second electrically conductive pillar includes
a conductor layer having a columnar shape, and
a barrier metal layer surrounding a periphery of the conductor layer.

### (4)

The semiconductor storage device according to (3), in which the conductor layer includes a conductor including tungsten.

### (5)

The semiconductor storage device according to (3) or (4), in which the barrier metal layer includes a metal material including at least one of titanium, titanium nitride, or ruthenium.

### (6)

The semiconductor storage device according to any one of (2) to (5), in which the second wiring is coupled to a side surface, of the electrode layer, that is on an opposite side to the second electrically conductive pillar.

### (7)

The semiconductor storage device according to any one of (2) to (6), in which the ferroelectric layer includes hafnium oxide.

### (8)

The semiconductor storage device according to (2), in which the electrode layer and at least a portion of the second wiring are integrated with each other.

### (9)

The semiconductor storage device according to (2), in which a part, of the second electrically conductive pillar, that is surrounded by the electrode layer only includes a conductor layer having a columnar shape.

### (10)

The semiconductor storage device according to (2), in which
the second electrically conductive pillar includes
   a conductor layer having a columnar shape,
   a barrier metal layer surrounding a periphery of a lower part of the conductor layer in the stack direction, and
   a counter electrode layer surrounding a periphery of an upper part of the conductor layer in the stack direction and opposed to the electrode layer, and
a material included in the barrier metal layer and a material included in the counter electrode layer are different from each other.

### (11)

A transistor device including:
a transistor including
   a gate electrode provided upright on a surface of a substrate,
   a channel layer having a sheet shape that passes through the gate electrode along the surface, and
   a source region and a drain region that are opposed to each other with the gate electrode and the channel layer interposed therebetween, and are each provided upright on the substrate; and
at least one of a first wiring or a second wiring, the first wiring being electrically coupled to a side surface of the source region, the second wiring being electrically coupled to a side surface of the drain region.

This application claims the benefit of Japanese Priority Patent Application JP 2022-201800 filed with the Japan Patent Office on Dec. 19, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A semiconductor storage device comprising:
a semiconductor substrate including a thin-film transistor;
a first wiring and a second wiring each stacked over the semiconductor substrate;
a contact part including a first electrically conductive pillar, the first electrically conductive pillar extending in a stack direction in which the first wiring and the second wiring are each stacked over the semiconductor substrate and electrically coupling the thin-film transistor and the first wiring to each other; and
a capacitor part including a second electrically conductive pillar, the second electrically conductive pillar extending in the stack direction and electrically coupling the thin-film transistor and the second wiring to each other, wherein
a height position of an upper end, of the first electrically conductive pillar, that is on an opposite side to the semiconductor substrate and a height position of an upper end, of the second electrically conductive pillar, that is on an opposite side to the semiconductor substrate substantially coincide with each other.

2. The semiconductor storage device according to claim 1, wherein the capacitor part includes
the second electrically conductive pillar,
an electrode layer surrounding a portion of a side surface of the second electrically conductive pillar, and
a ferroelectric layer interposed between the second electrically conductive pillar and the electrode layer.

3. The semiconductor storage device according to claim 2, wherein the second electrically conductive pillar includes
a conductor layer having a columnar shape, and
a barrier metal layer surrounding a periphery of the conductor layer.

4. The semiconductor storage device according to claim 3, wherein the conductor layer includes a conductor including tungsten.

5. The semiconductor storage device according to claim 3, wherein the barrier metal layer includes a metal material including at least one of titanium, titanium nitride, or ruthenium.

6. The semiconductor storage device according to claim 2, wherein the second wiring is coupled to a side surface, of the electrode layer, that is on an opposite side to the second electrically conductive pillar.

7. The semiconductor storage device according to claim 2, wherein the ferroelectric layer includes hafnium oxide.

8. The semiconductor storage device according to claim 2, wherein the electrode layer and at least a portion of the second wiring are integrated with each other.

9. The semiconductor storage device according to claim 2, wherein a part, of the second electrically conductive pillar, that is surrounded by the electrode layer only includes a conductor layer having a columnar shape.

10. The semiconductor storage device according to claim 2, wherein
the second electrically conductive pillar includes
a conductor layer having a columnar shape,
a barrier metal layer surrounding a periphery of a lower part of the conductor layer in the stack direction, and
a counter electrode layer surrounding a periphery of an upper part of the conductor layer in the stack direction and opposed to the electrode layer, and
a material included in the barrier metal layer and a material included in the counter electrode layer are different from each other.

11. A transistor device comprising:
a transistor including
a gate electrode provided upright on a surface of a substrate,
a channel layer having a sheet shape that passes through the gate electrode along the surface, and
a source region and a drain region that are opposed to each other with the gate electrode and the channel layer interposed therebetween, and are each provided upright on the substrate; and
at least one of a first wiring or a second wiring, the first wiring being electrically coupled to a side surface of the source region, the second wiring being electrically coupled to a side surface of the drain region.
